(19) United States
(12) Patent Application Publication
(10) Pub. No.: US 2023/0086074 A1
(43) Pub. Date: Mar. 23, 2023

(54) SEMICONDUCTOR DEVICE, SEMICONDUCTOR MEMORY DEVICE, AND METHOD FOR MANUFACTURING SEMICONDUCTOR DEVICE

(71) Applicant: Kioxia Corporation, Tokyo (JP)

(72) Inventors: Yusuke NAKAJIMA, Yokohama (JP); Akira TAKASHIMA, Fuchu (JP); Tsunehiro INO, Fujisawa (JP); Yasushi NAKASAKI, Yokohama (JP); Koji USUDA, Yokohama (JP); Masaki NOGUCHI, Yokkaichi (JP)

(73) Assignee: Kioxia Corporation, Tokyo (JP)

(21) Appl. No.: 17/694,098

(22) Filed: Mar. 14, 2022

(30) Foreign Application Priority Data
Sep. 17, 2021 (JP) 2021-151983

(51) Int. Cl. H01L 27/11582; H01L 27/11519; H01L 27/11524; H01L 27/11556; H01L 27/11565; H01L 27/1157

(52) U.S. Cl. CPC H01L 27/11582; H01L 27/11519; H01L 27/11524; H01L 27/11556; H01L 27/11565; H01L 27/1157

(57) ABSTRACT

A semiconductor device of an embodiment includes a semiconductor layer, a gate electrode layer, and a first insulating layer provided between the semiconductor layer and the gate electrode layer, the first insulating layer including aluminum oxide including at least one crystal phase selected from the group consisting of alpha (α)-aluminum oxide and theta (θ)-aluminum oxide, the first insulating layer having a thickness of equal to or less than 2.5 nm in a first direction from the semiconductor layer toward the gate electrode layer.

### CROSS-REFERENCE TO RELATED APPLICATION

This application is based upon and claims the benefit of priority from Japanese Patent Application No. 2021-151983, filed on Sep. 17, 2021, the entire contents of which are incorporated herein by reference.

### FIELD

Embodiments described herein relate generally to a semiconductor device, a semiconductor memory device, and a method for manufacturing a semiconductor device.

### BACKGROUND

For example, a logic device includes a scaled-down metal oxide field effect transistor (MOSFET) in order to improve performance of the device. A gate insulating layer having a small thickness and a small leakage current is required for the scaled-down MOSFET.

A three-dimensional NAND flash memory in which memory cells are three-dimensionally disposed achieves a high degree of integration and a low cost. The three-dimensional NAND flash memory includes, for example, a stacked body in which a plurality of insulating layers and a plurality of gate electrode layers are alternately stacked, and a memory hole formed so as to penetrate the stacked body. In the memory hole, a charge storage layer and a semiconductor layer are formed to form a memory string in which a plurality of memory cells are connected in series. Each memory cell has a block insulating layer to inhibit the charges held in the charge storage layer from leaking into the gate electrode. A block insulating layer having a small thickness and a small leakage current is required for scaling-down of the memory cell.

### BRIEF DESCRIPTION OF THE DRAWINGS

FIG. 1 is a schematic sectional view of a semiconductor device of a first embodiment;

FIGS. 2A, 2B, 2C, and 2D are explanatory views of a method for manufacturing the semiconductor device of the first embodiment;

FIG. 3 is a schematic sectional view of a modified example of the semiconductor device of the first embodiment;

FIGS. 4A, 4B, 4C, 4D, and 4E are explanatory views of a modified example of the method for manufacturing the semiconductor device of the first embodiment;

FIG. 5 is a circuit diagram of a memory cell array of a semiconductor memory device of a second embodiment;

FIGS. 6A and 6B are schematic sectional views of the memory cell array of the semiconductor memory device of the second embodiment;

FIG. 7 is a schematic sectional view illustrating an example of a method for manufacturing the semiconductor memory device of the second embodiment;

FIG. 8 is a schematic sectional view illustrating an example of the method for manufacturing the semiconductor memory device of the second embodiment;

FIG. 9 is a schematic sectional view illustrating an example of the method for manufacturing the semiconductor memory device of the second embodiment;

FIG. 10 is a schematic sectional view illustrating an example of the method for manufacturing the semiconductor memory device of the second embodiment;

FIG. 11 is a schematic sectional view illustrating an example of the method for manufacturing the semiconductor memory device of the second embodiment;

FIG. 12 is a schematic sectional view illustrating an example of the method for manufacturing the semiconductor memory device of the second embodiment;

FIG. 13 is a schematic sectional view illustrating an example of the method for manufacturing the semiconductor memory device of the second embodiment;

FIG. 14 is a schematic sectional view illustrating an example of the method for manufacturing the semiconductor memory device of the second embodiment;

FIG. 15 is a schematic sectional view illustrating an example of the method for manufacturing the semiconductor memory device of the second embodiment;

FIG. 16 is a circuit diagram of a memory cell array of a semiconductor memory device of a third embodiment;

FIG. 17 is a schematic sectional view of the memory cell array of the semiconductor memory device of the third embodiment; and

FIGS. 18A and 18B are schematic sectional views of the memory cell array of the semiconductor memory device of the third embodiment.

### DETAILED DESCRIPTION

A semiconductor device of an embodiment includes a semiconductor layer, a gate electrode layer, and a first insulating layer provided between the semiconductor layer and the gate electrode layer, the first insulating layer including aluminum oxide including at least one crystal phase selected from the group consisting of alpha (α)-aluminum oxide and theta (θ)-aluminum oxide, the first insulating layer having a thickness of equal to or less than 2.5 nm in a first direction from the semiconductor layer toward the gate electrode layer.

Hereinafter, embodiments of the present disclosure will be described with reference to the drawings. In the following description, the same reference symbol is given to the same or similar members and the like, and the description of the members and the like once described is appropriately omitted.

In the present description, the terms “upper” and “lower” may be used for convenience. The terms “upper” and “lower” indicate, for example, a relative positional relationship in the drawings. The terms “upper” and “lower” do not necessarily define a positional relationship with respect to gravity.

For qualitative analysis and quantitative analysis of the chemical composition of members included in a semiconductor device or a semiconductor memory device in the present description, for example, secondary ion mass spectroscopy (SIMS), energy dispersive X-ray spectroscopy (EDX), and electron energy loss spectroscopy (EELS) can be used. In addition, for example, a transmission electron microscope (TEM) can be used for measuring the thickness of the members included in the semiconductor device or the semiconductor memory device, the distance between the members, and the like. For identifying the crystal systems of constituent substances of the members included in the semiconductor memory device and comparing the existence ratios of the crystal systems, for example, a transmission electron microscope, X-ray diffraction (XRD), electron beam diffraction (EBD), X-ray photoelectron spectroscopy (XPS), and synchrotron radiation X-ray absorption fine structure (XAFS) can be used. In addition, for example, fast Fourier transform analysis on an image obtained by TEM enables evaluation of the orientation of the crystal axes.

### First Embodiment

A semiconductor device of a first embodiment includes a semiconductor layer, a gate electrode layer, and a first insulating layer provided between the semiconductor layer and the gate electrode layer, the first insulating layer including aluminum oxide including at least one crystal phase selected from the group consisting of alpha (α)-aluminum oxide and theta (e)-aluminum oxide, the first insulating layer having a thickness of equal to or less than 2.5 nm in a first direction from the semiconductor layer toward the gate electrode layer.

The semiconductor device of the first embodiment includes a semiconductor layer, a gate electrode layer, and a first insulating layer provided between the semiconductor layer and the gate electrode layer, the first insulating layer including aluminum oxide including at least one crystal phase selected from the group consisting of alpha (α)-aluminum oxide and theta (e)-aluminum oxide, the aluminum oxide having a crystal axis in a direction within a range of ±10 degrees with respect to a first direction from the semiconductor layer toward the gate electrode layer.

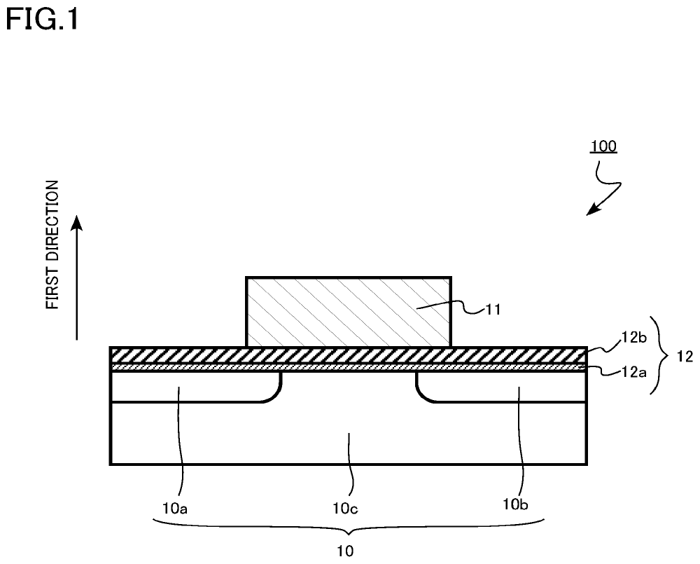

FIG. 1 is a schematic sectional view of the semiconductor device of the first embodiment. The semiconductor device of the first embodiment is a MOSFET 100. The MOSFET 100 is a MOSFET having a planar gate structure.

The MOSFET 100 includes a semiconductor layer 10, a gate electrode layer 11, and a gate insulating layer 12. The semiconductor layer 10 includes a source region 10a, a drain region 10b, and a channel region 10c. The gate insulating layer 12 includes a lower layer 12a and an upper layer 12b.

The lower layer 12a is an example of a second insulating layer. The upper layer 12b is an example of the first insulating layer.

The semiconductor layer 10 is a semiconductor. The semiconductor layer 10 is, for example, a single crystal. The semiconductor layer 10 is, for example, silicon. The semiconductor layer 10 is, for example, an oxide semiconductor.

The semiconductor layer 10 includes the source region 10a, the drain region 10b, and the channel region 10c. The channel region 10c is provided between the source region 10a and the drain region 10b.

The source region 10a and the drain region 10b are, for example, an n-type semiconductor. The channel region 10c is, for example, a p-type semiconductor.

The gate electrode layer 11 is a conductor. The gate electrode layer 11 includes, for example, a metal, a metal-semiconductor compound, or a semiconductor containing a conductive impurity.

The gate insulating layer 12 is provided between the semiconductor layer 10 and the gate electrode layer 11. The gate insulating layer 12 includes the lower layer 12a and the upper layer 12b.

The upper layer 12b is provided between the semiconductor layer 10 and the gate electrode layer 11. The lower layer 12a is provided between the semiconductor layer 10 and the upper layer 12b.

The lower layer 12a is an insulating layer. The lower layer 12a includes, for example, silicon (Si) and oxygen (O). The lower layer 12a includes, for example, silicon oxide. The lower layer 12a is, for example, a silicon oxide layer.

The lower layer 12a has, for example, a function of reducing the interface state of the interface between the semiconductor layer 10 and the gate insulating layer 12.

The lower layer 12a has a thickness of, for example, equal to or more than 0.3 nm and equal to or less than 2 nm in the first direction from the semiconductor layer 10 toward the gate electrode layer 11.

The upper layer 12b is an insulating layer. The upper layer 12b includes aluminum oxide. The upper layer 12b is, for example, an aluminum oxide layer.

The aluminum oxide included in the upper layer 12b includes at least one crystal phase selected from the group consisting of alpha (α)-aluminum oxide and theta (e)-aluminum oxide. The aluminum oxide included in the upper layer 12b includes α-aluminum oxide or θ-aluminum oxide, or includes both α-aluminum oxide and θ-aluminum oxide.

α-Aluminum oxide has a crystal structure of a hexagonal crystal. θ-Aluminum oxide has a crystal structure of a monoclinic crystal.

The aluminum oxide included in the upper layer 12b may include gamma (γ)-aluminum oxide. γ-Aluminum oxide has a crystal structure of a cubic crystal.

α-Aluminum oxide is also referred to as α-alumina, θ-aluminum oxide is also referred to as θ-alumina, and γ-aluminum oxide is also referred to as γ-alumina.

The aluminum oxide in the upper layer 12b has a crystal axis in a direction within a range of ±10 degrees with respect to the first direction. The aluminum oxide in the upper layer 12b is uniaxially oriented. The aluminum oxide in the upper layer 12b has a c-axis in a direction within a range of ±10 degrees with respect to the first direction.

The angle between the direction of the crystal axis of the aluminum oxide in the upper layer 12b and the first direction can be determined, for example, as follows. A TEM image of a section of the upper layer 12b is subjected to fast Fourier transform analysis to determine the spot array direction, and the spot array direction is compared with the first direction to determine the angle.

The upper layer 12b has a thickness of, for example, equal to or more than 0.5 nm and equal to or less than 2.5 nm in the first direction from the semiconductor layer 10 toward the gate electrode layer 11.

The MOSFET 100 can have a structure in which the lower layer 12a is omitted and the upper layer 12b is in contact with the semiconductor layer 10.

Next, a method for manufacturing the semiconductor device of the first embodiment will be described. The method for manufacturing the semiconductor device of the first embodiment includes forming a first aluminum nitride film having a thickness of less than 2.5 nm, and forming a first aluminum oxide film by oxidizing the first aluminum nitride film at a temperature of equal to or more than 900° C.

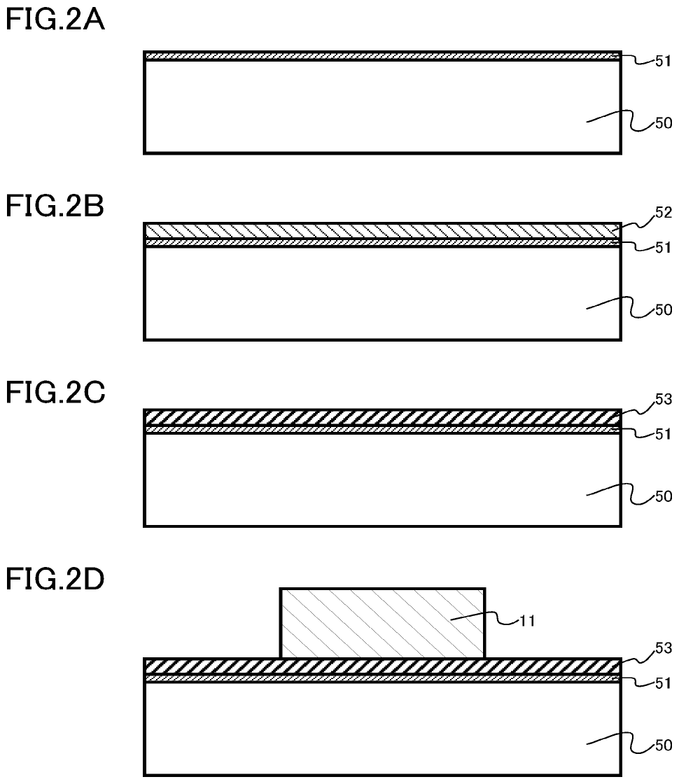

FIGS. 2A, 2B, 2C, and 2D are explanatory views of the method for manufacturing the semiconductor device of the first embodiment.

First, a p-type single crystal silicon layer 50 is prepared. The single crystal silicon layer 50 is an example of the semiconductor layer.

Next, a silicon oxide film 51 is formed on the single crystal silicon layer 50 (FIG. 2A). The silicon oxide film 51 is formed by, for example, thermally oxidizing the surface of the single crystal silicon layer 50. The silicon oxide film 51 finally serves as the lower layer 12a. The silicon oxide film 51 has a thickness of, for example, equal to or more than 0.3 nm and equal to or less than 2 nm.

Next, a first aluminum nitride film 52 is formed on the silicon oxide film 51 (FIG. 2B). The first aluminum nitride film 52 has a thickness of, for example, equal to or more than 0.5 nm and less than 2.5 nm. The first aluminum nitride film 52 is formed with, for example, an atomic layer deposition (ALD) method.

Next, the first aluminum nitride film 52 is oxidized to form a first aluminum oxide film 53 (FIG. 2C). The first aluminum nitride film 52 is oxidized, for example, at a temperature of equal to or more than 900° C. and equal to or less than 1,150° C.

The first aluminum nitride film 52 is oxidized, for example, in an atmosphere containing hydrogen. The first aluminum nitride film 52 is oxidized, for example, in an atmosphere containing an oxygen gas and a hydrogen gas. The first aluminum nitride film 52 is oxidized by, for example, in-situ steam generation (ISSG).

The aluminum nitride film is oxidized to form an aluminum oxide film having a larger thickness than the aluminum nitride film.

The first aluminum oxide film 53 finally serves as the upper layer 12b. The lower layer 12a and the upper layer 12b serve as the gate insulating layer 12.

Next, a gate electrode layer 11 is formed on the first aluminum oxide film 53 with a publicly known process technique (FIG. 2D). Then, an n-type impurity region is formed in the single crystal silicon layer 50 using an ion implantation method. The n-type impurity region serves as the source region 10a and the drain region 10b.

The MOSFET 100 illustrated in FIG. 1 is manufactured with the above-described method for manufacturing.

Next, functions and effects of the semiconductor device of the first embodiment and the method for manufacturing the semiconductor device will be described.

For example, a logic device includes a scaled-down MOSFET in order to improve performance of the device. The scaled-down MOSFET is to include a gate insulating layer achieving a small thickness and a small leakage current.

The MOSFET 100 of the first embodiment includes the gate insulating layer 12 including the upper layer 12b having a thickness as small as equal to or less than 2.5 nm. The aluminum oxide included in the upper layer 12b includes at least one crystal phase selected from the group consisting of α-aluminum oxide and θ-aluminum oxide. The aluminum oxide included in the upper layer 12b includes α-aluminum oxide or θ-aluminum oxide, or includes both α-aluminum oxide and θ-aluminum oxide, resulting in reduction in leakage current of the upper layer 12b. α-Aluminum oxide and θ-aluminum oxide are considered to achieve a smaller leakage current than other crystal phases such as γ-aluminum oxide.

From the viewpoint of reducing the leakage current of the gate insulating layer 12, at least one crystal phase selected from the group consisting of α-aluminum oxide and θ-aluminum oxide is preferably the main crystal phase among the crystal phases of the aluminum oxide included in the upper layer 12b. The term “main crystal phase” means a crystal phase having a higher existence ratio than other crystal phases.

The aluminum oxide in the upper layer 12b has a crystal axis in a direction within a range of ±10 degrees with respect to the first direction. That is, the aluminum oxide in the upper layer 12b is uniaxially oriented. The uniaxial orientation of the aluminum oxide in the upper layer 12b leads to reduction in leakage current of the upper layer 12b. The reason for reduction in leakage current is considered to be increase in crystallinity of the aluminum oxide in the upper layer 12b.

From the viewpoint of reducing the leakage current of the gate insulating layer 12, the aluminum oxide in the upper layer 12b preferably has a crystal axis in a direction within a range of ±5 degrees with respect to the first direction.

The gate insulating layer 12 of the first embodiment is formed with the method for manufacturing of the first embodiment. In the method for manufacturing of the first embodiment, an aluminum nitride film having a thickness of less than 2.5 nm is oxidized to form an aluminum oxide film. The leakage current can be reduced with this method of manufacturing even if the aluminum oxide film has a thickness as small as equal to or less than 2.5 nm. For example, the leakage current of the aluminum oxide film manufactured with the method of the first embodiment can be reduced to a leakage current lower by equal to or more than one order than that of an aluminum oxide film having the same film thickness formed with a chemical vapor deposition method (CVD method).

However, the leakage current is increased in an aluminum oxide film formed by oxidizing a thick aluminum nitride film having a thickness of equal to or more than 2.5 nm. If the aluminum nitride film has a thickness of equal to or more than 2.5 nm, the surface roughness after the oxidation is rapidly increased. The rapid increase in surface roughness is considered to cause increase in leakage current.

In the method for manufacturing of the first embodiment, the oxidation temperature of the aluminum nitride film is preferably equal to or more than 950° C. and equal to or less than 1,100° C., and more preferably equal to or more than 1,000° C. and equal to or less than 1,050° C., from the viewpoint of reducing the leakage current of the gate insulating layer 12.

In the method for manufacturing of the first embodiment, the atmosphere of the oxidation of the aluminum nitride film preferably contains hydrogen from the viewpoint of reducing the leakage current of the gate insulating layer 12. The atmosphere of the oxidation of the aluminum nitride film particularly preferably contains an oxygen gas and a hydrogen gas.

In the method for manufacturing of the first embodiment, the first aluminum nitride film 52 preferably has a thickness of equal to or less than 2.0 nm from the viewpoint of reducing the surface roughness after the oxidation.

In the MOSFET 100 of the first embodiment, the upper layer 12b preferably has a thickness of equal to or less than 2.0 nm in the first direction from the viewpoint of reducing the leakage current of the gate insulating layer 12.

### Modified Example

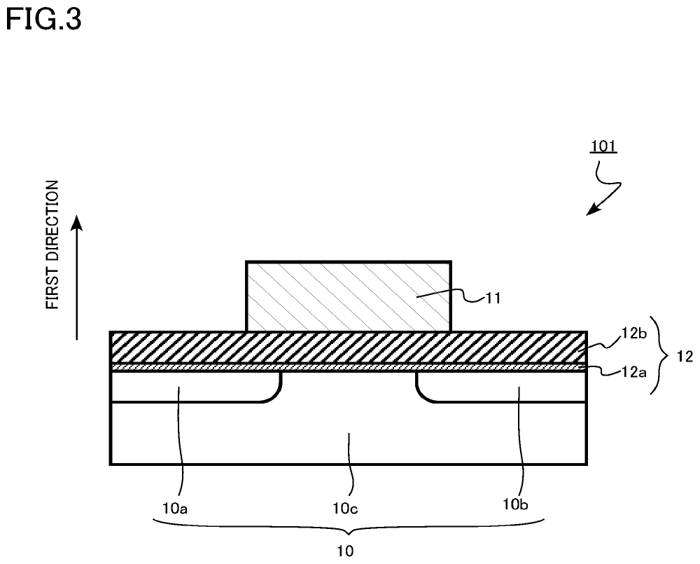

FIG. 3 is a schematic sectional view of a modified example of the semiconductor device of the first embodiment. The modified example of the semiconductor device of the first embodiment is different from the semiconductor device of the first embodiment in that the first insulating layer in the modified example has a thickness of more than 2.5 nm.

The modified example of the semiconductor device of the first embodiment is a MOSFET 101.

The upper layer 12b in the MOSFET 101 has a thickness of, for example, more than 2.5 nm in the first direction. The upper layer 12b has a thickness of, for example, equal to or less than 30 nm in the first direction.

Next, a modified example of the method for manufacturing the semiconductor device of the first embodiment will be described. The method of the modified example of the method for manufacturing the semiconductor device of the first embodiment is different from the method of manufacturing the semiconductor device of the first embodiment in that the method of the modified example further includes, after forming the first aluminum oxide film, forming a second aluminum nitride film having a thickness of less than 2.5 nm on the first aluminum oxide film, and oxidizing the second aluminum nitride film at a temperature of equal to or more than 900° C. to form a second aluminum oxide film.

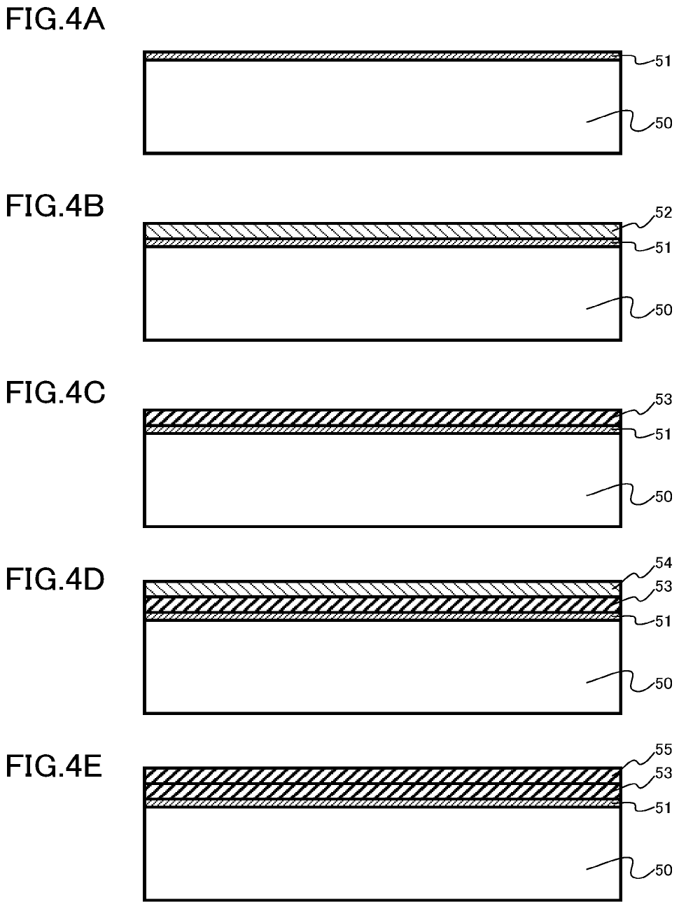

FIGS. 4A, 4B, 4C, 4D, and 4E are explanatory views of the modified example of the method for manufacturing the semiconductor device of the first embodiment.

First, a p-type single crystal silicon layer 50 is prepared. The single crystal silicon layer 50 is an example of the semiconductor layer.

Next, a silicon oxide film 51 is formed on the single crystal silicon layer 50 (FIG. 4A). The silicon oxide film 51 is formed by, for example, thermally oxidizing the surface of the single crystal silicon layer 50. The silicon oxide film 51 finally serves as the lower layer 12a.

Next, a first aluminum nitride film 52 is formed on the silicon oxide film 51 (FIG. 4B). The first aluminum nitride film 52 has a thickness of, for example, equal to or more than 0.5 nm and less than 2.5 nm. The first aluminum nitride film 52 is formed with, for example, an ALD method.

Next, the first aluminum nitride film 52 is oxidized to form a first aluminum oxide film 53 (FIG. 4C). The first aluminum nitride film 52 is oxidized, for example, at a temperature of equal to or more than 900° C. and equal to or less than 1,150° C.

The first aluminum nitride film 52 is oxidized, for example, in an atmosphere containing hydrogen. The first aluminum nitride film 52 is oxidized, for example, in an atmosphere containing an oxygen gas and a hydrogen gas. The first aluminum nitride film 52 is oxidized, for example, by ISSG.

The first aluminum oxide film 53 finally serves as a part of the upper layer 12b.

Next, a second aluminum nitride film 54 is formed on the first aluminum oxide film 53 (FIG. 4D). The second aluminum nitride film 54 has a thickness of, for example, equal to or more than 0.5 nm and less than 2.5 nm. The second aluminum nitride film 54 is formed with, for example, an ALD method.

Next, the second aluminum nitride film 54 is oxidized to form a second aluminum oxide film 55 (FIG. 4E). The second aluminum nitride film 54 is oxidized, for example, at a temperature of equal to or more than 900° C. and equal to or less than 1,150° C.

The second aluminum nitride film 54 is oxidized, for example, in an atmosphere containing hydrogen. The second aluminum nitride film 54 is oxidized, for example, in an atmosphere containing an oxygen gas and a hydrogen gas. The second aluminum nitride film 54 is oxidized, for example, by ISSG.

The second aluminum oxide film 55 finally serves as a part of the upper layer 12b. The stacked film of the first aluminum oxide film 53 and the second aluminum oxide film 55 has a thickness of, for example, more than 2.5 nm. The stacked film of the first aluminum oxide film 53 and the second aluminum oxide film 55 finally serves as the gate insulating layer 12.

Next, a gate electrode layer 11 is formed on the second aluminum oxide film 55 with a publicly known process technique. Then, an n-type impurity region is formed in the single crystal silicon layer 50 using an ion implantation method. The n-type impurity region serves as the source region 10a and the drain region 10b.

The MOSFET 101 illustrated in FIG. 3 is manufactured with the above-described method.

After forming the second aluminum oxide film 55, formation of an aluminum nitride film and oxidation of the aluminum nitride film can be further repeated to further increase the thickness of the upper layer 12b.

According to the MOSFET 101 of the modified example, the leakage current of the gate insulating layer 12 can be reduced even if the upper layer 12b has a thickness of more than 2.5 nm.

As described above, the leakage current is increased in an aluminum oxide film formed by oxidizing a thick aluminum nitride film having a thickness of equal to or more than 2.5 nm. According to the method for manufacturing of the modified example of the first embodiment, an aluminum oxide film having a thickness of equal to or more than 2.5 nm, the aluminum oxide film in which the leakage current is reduced can be formed by repeating formation and oxidation of an aluminum nitride film having a thickness of less than 2.5 nm.

As described above, according to the first embodiment and the modified example of the first embodiment, a semiconductor device including an insulating layer achieving a small leakage current can be provided. Furthermore, according to the first embodiment and the modified example of the first embodiment, a method for manufacturing a semiconductor device including an insulating layer achieving a small leakage current can be provided.

### Second Embodiment

A semiconductor memory device of a second embodiment includes a semiconductor layer extending in a first direction, a gate electrode layer, a charge storage layer provided between the semiconductor layer and the gate electrode layer, a first insulating layer provided between the charge storage layer and the gate electrode layer, the first insulating layer including aluminum oxide including at least one crystal phase selected from the group consisting of alpha (α)-aluminum oxide and theta (θ)-aluminum oxide, the first insulating layer having a thickness of equal to or less than 2.5 nm in a second direction from the semiconductor layer toward the gate electrode layer, and a second insulating layer provided between the charge storage layer and the semiconductor layer.

The semiconductor memory device of the second embodiment includes a semiconductor layer extending in a first direction, a gate electrode layer, a charge storage layer provided between the semiconductor layer and the gate electrode layer, a first insulating layer provided between the charge storage layer and the gate electrode layer, the first insulating layer including aluminum oxide including at least one crystal phase selected from the group consisting of alpha (α)-aluminum oxide and theta (θ)-aluminum oxide, the aluminum oxide having a crystal axis in a direction within a range of ±10 degrees with respect to a second direction from the semiconductor layer toward the gate electrode layer, and a second insulating layer provided between the charge storage layer and the semiconductor layer.

The semiconductor memory device of the second embodiment is a three-dimensional NAND flash memory. The memory cell of the semiconductor memory device of the second embodiment is a so-called metal-oxide-nitride-oxide-semiconductor (MONOS) memory cell.

The memory cell of the semiconductor memory device of the second embodiment includes, as a block insulating layer, an insulating layer similar to the first insulating layer of the semiconductor device of the first embodiment, the insulating layer including aluminum oxide. The block insulating layer in the memory cell of the semiconductor memory device of the second embodiment is formed using the same method as the method for manufacturing the semiconductor device of the first embodiment. Hereinafter, the same description as the description of the first embodiment may be partially omitted.

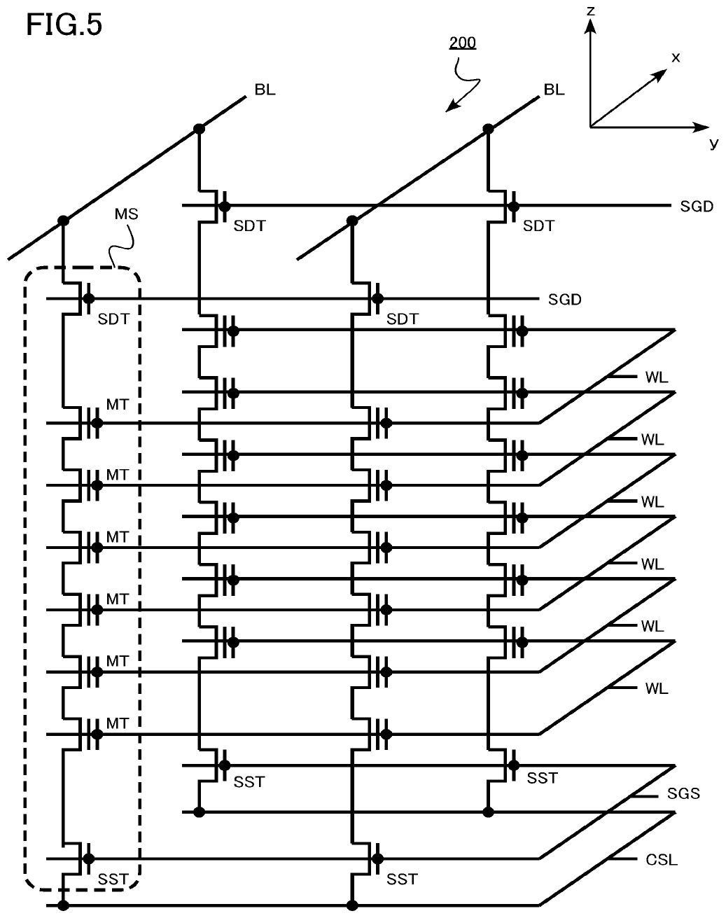

FIG. 5 is a circuit diagram of the memory cell array of the semiconductor memory device of the second embodiment.

As illustrated in FIG. 5, a memory cell array 200 of the three-dimensional NAND flash memory of the second embodiment includes a plurality of word lines WL, a common source line CSL, a source selection gate line SGS, a plurality of drain selection gate lines SGD, a plurality of bit lines BL, and a plurality of memory strings MS.

The word lines WL are disposed apart from each other in the z direction. The word lines WL are stacked and disposed in the z direction. The memory strings MS extend in the z direction. The bit lines BL extend, for example, in the x direction.

Hereinafter, the x direction is defined as the third direction, the y direction is defined as the second direction, and the z direction is defined as the first direction. The x direction, the y direction, and the z direction cross each other, and are, for example, perpendicular to each other.

As illustrated in FIG. 5, each memory string MS includes a source selection transistor SST, a plurality of memory cells, and a drain selection transistor SDT connected in series between the common source line CSL and the bit line BL. One bit line BL and one drain selection gate line SGD are selected to select one memory string MS, and one word line WL can be selected to select one memory cell. The word line WL is a gate electrode of the memory cell transistor MT included in the memory cell.

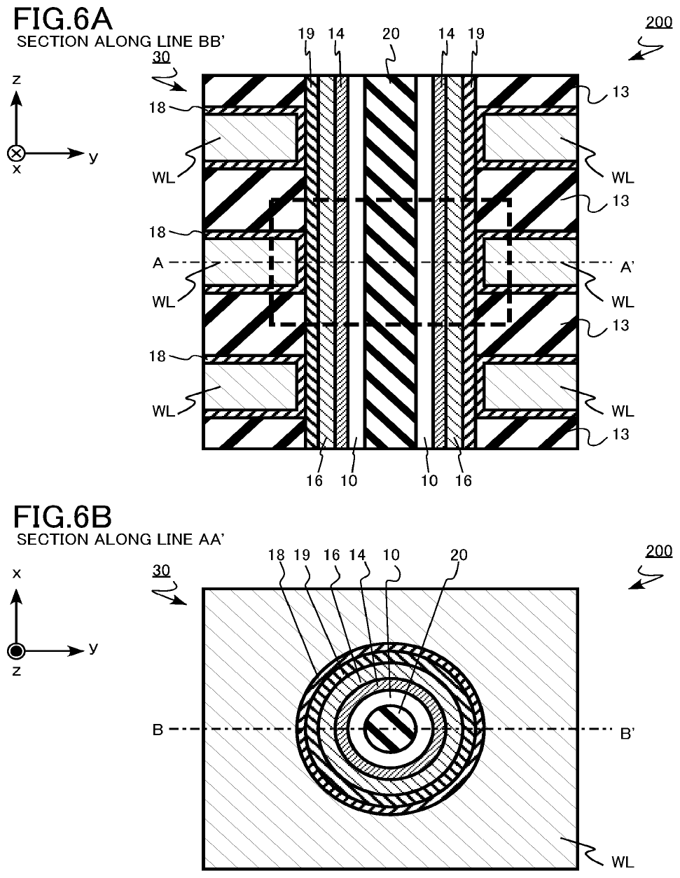

FIGS. 6A and 6B are schematic sectional views of the memory cell array of the semiconductor memory device of the second embodiment. FIGS. 6A and 6B illustrate a section of a plurality of memory cells in one memory string MS in the memory cell array 200 of FIG. 5.

FIG. 6A is a yz sectional view of the memory cell array 200. FIG. 6A illustrates the section along the line BB′ in FIG. 6B. FIG. 6B is an xy sectional view of the memory cell array 200. FIG. 6B illustrates the section along the line AA′ in FIG. 6A. In FIG. 6A, the region surrounded by the broken line is one memory cell.

As illustrated in FIGS. 6A and 6B, the memory cell array 200 includes word lines WL, a semiconductor layer 10, interlayer insulating layers 13, a tunnel insulating layer 14, a charge storage layer 16, first block insulating layers 18, a second block insulating layer 19, and a core insulating region 20. A stacked body 30 includes the word lines WL and the interlayer insulating layers 13.

Each word line WL is an example of the gate electrode layer. Each interlayer insulating layer 13 is an example of a fourth insulating layer. The tunnel insulating layer 14 is an example of the second insulating layer. The first block insulating layer 18 is an example of the first insulating layer. The second block insulating layer 19 is an example of a third insulating layer.

The memory cell array 200 is provided, for example, on a semiconductor substrate (not illustrated). The semiconductor substrate has a surface parallel to the x direction and the y direction.

The word lines WL and the interlayer insulating layers 13 are alternately stacked on the semiconductor substrate in the z direction. The word lines WL are disposed apart from each other in the z direction repeatedly. The stacked body 30 includes the word lines WL and the interlayer insulating layers 13. Each word line WL functions as a control electrode of the memory cell transistor MT.

The word line WL is a plate-shaped conductor. The word line WL is, for example, a metal, a metal nitride, a metal carbide, or a semiconductor. The word line WL has, for example, a stacked structure of a metal nitride and a metal. The word line WL has, for example, a stacked structure of titanium nitride and tungsten (W). The word line WL has a thickness of, for example, equal to or more than 5 nm and equal to or less than 20 nm in the z direction.

Each interlayer insulating layer 13 separates two word lines WL. The interlayer insulating layer 13 electrically separates two word lines WL.

The interlayer insulating layer 13 is, for example, an oxide, an oxynitride, or a nitride. The interlayer insulating layer 13 includes, for example, silicon (Si) and oxygen (O). The interlayer insulating layer 13 is, for example, silicon oxide. The interlayer insulating layer 13 has a thickness of, for example, equal to or more than 5 nm and equal to or less than 20 nm in the z direction.

The semiconductor layer 10 is provided in the stacked body 30. The semiconductor layer 10 extends in the z direction. The semiconductor layer 10 extends in the direction perpendicular to the surface of the semiconductor substrate.

The semiconductor layer 10 is provided so as to penetrate the stacked body 30. The semiconductor layer 10 is surrounded by the word lines WL. The semiconductor layer 10 has, for example, a cylindrical shape. The semiconductor layer 10 functions as a channel of the memory cell transistor MT.

The semiconductor layer 10 is, for example, a polycrystalline semiconductor. The semiconductor layer 10 is, for example, polycrystalline silicon.

The tunnel insulating layer 14 is provided between the semiconductor layer 10 and the word line WL. The tunnel insulating layer 14 is provided between the semiconductor layer 10 and at least one of the word lines WL. The tunnel insulating layer 14 is provided between the semiconductor layer 10 and the charge storage layer 16. The tunnel insulating layer 14 has a function of passing charges according to the voltage applied between the word line WL and the semiconductor layer 10.

The tunnel insulating layer 14 includes, for example, silicon (Si), nitrogen (N), and oxygen (O). The tunnel insulating layer 14 includes, for example, silicon oxide, silicon nitride, or silicon oxynitride. The tunnel insulating layer 14 has a thickness of, for example, equal to or more than 3 nm and equal to or less than 8 nm.

The charge storage layer 16 is provided between the tunnel insulating layer 14 and the first block insulating layer 18. The charge storage layer 16 is provided between the tunnel insulating layer 14 and the second block insulating layer 19.

The charge storage layer 16 has a function of trapping and storing charges. The charges are, for example, electrons. The threshold voltage of the memory cell transistor MT changes according to the amount of charges stored in the charge storage layer 16. One memory cell can store data by using this change in the threshold voltage.

For example, change in the threshold voltage of the memory cell transistor MT causes change in the turn-on voltage of the memory cell transistor MT. For example, a state in which the threshold voltage is high is defined as data “0”, a state in which the threshold voltage is low is defined as data “1”, and thus the memory cell can store 1-bit data of “0” and “1”.

The charge storage layer 16 is, for example, an insulating layer. The charge storage layer 16 includes, for example, silicon (Si) and nitrogen (N). The charge storage layer 16 includes, for example, silicon nitride. The charge storage layer 16 has a thickness of, for example, equal to or more than 3 nm and equal to or less than 10 nm.

The first block insulating layer 18 and the second block insulating layer 19 are provided between the tunnel insulating layer 14 and the word line WL. The first block insulating layer 18 and the second block insulating layer 19 are provided between the charge storage layer 16 and the word line WL. The first block insulating layer 18 and the second block insulating layer 19 have a function of blocking the current flow between the charge storage layer 16 and the word line WL.

The first block insulating layer 18 is provided between the charge storage layer 16 and the word line WL. The first block insulating layer 18 is provided between the second block insulating layer 19 and the word line WL.

The interlayer insulating layer 13 is provided in the z direction of the word line WL. The word line WL and the interlayer insulating layer 13 are arranged in the z direction. The first block insulating layer 18 is provided between the word line WL and the Interlayer insulating layer 13 in the z direction.

The first block insulating layer 18 is an insulating layer. The first block insulating layer 18 includes aluminum oxide. The first block insulating layer 18 is, for example, an aluminum oxide layer.

The aluminum oxide included in the first block insulating layer 18 includes at least one crystal phase selected from the group consisting of alpha (α)-aluminum oxide and theta (θ)-aluminum oxide.

α-Aluminum oxide has a crystal structure of a hexagonal crystal. θ-Aluminum oxide has a crystal structure of a monoclinic crystal.

The aluminum oxide included in the first block insulating layer 18 may include gamma (γ)-aluminum oxide. γ-Aluminum oxide has a crystal structure of a cubic crystal.

The aluminum oxide in the first block insulating layer 18 has a crystal axis in a direction within a range of ±10 degrees with respect to the y direction from the semiconductor layer 10 toward the word line WL. The aluminum oxide in the first block insulating layer 18 is uniaxially oriented. The aluminum oxide in the first block insulating layer 18 has a c-axis in a direction, for example, within a range of ±10 degrees with respect to the y direction.

The angle between the direction of the crystal axis of the aluminum oxide in the first block insulating layer 18 and the y direction can be determined, for example, as follows. A TEM image of a section of the first block insulating layer 18 is subjected to fast Fourier transform analysis to determine the spot array direction, and the spot array direction is compared with the y direction to determine the angle.

The first block insulating layer 18 has a thickness of, for example, equal to or more than 0.5 nm and equal to or less than 2.5 nm in the y direction from the semiconductor layer 10 toward the word line WL.

The second block insulating layer 19 is provided between the charge storage layer 16 and the first block insulating layer 18. The second block insulating layer 19 is provided between the interlayer insulating layer 13 and the semiconductor layer 10. The second block insulating layer 19 is provided between the interlayer insulating layer 13 and the charge storage layer 16.

The second block insulating layer 19 is an insulating layer. The second block insulating layer 19 includes, for example, silicon (Si) and oxygen (O). The second block insulating layer 19 includes, for example, silicon oxide. The second block insulating layer 19 is, for example, a silicon oxide layer.

The second block insulating layer 19 has a thickness of, for example, equal to or more than 3 nm and equal to or less than 8 nm in the y direction.

The core insulating region 20 is provided in the stacked body 30. The core insulating region 20 extends in the z direction. The core insulating region 20 is provided so as to penetrate the stacked body 30. The core insulating region 20 is surrounded by the semiconductor layer 10. The core insulating region 20 is surrounded by the word lines WL. The core insulating region 20 has a columnar shape. The core insulating region 20 has, for example, a cylindrical shape.

The core insulating region 20 is, for example, an oxide, an oxynitride, or a nitride. The core insulating region 20 includes, for example, silicon (Si) and oxygen (O). The core insulating region 20 is, for example, silicon oxide.

Next, an example of a method for manufacturing the semiconductor memory device of the second embodiment will be described.

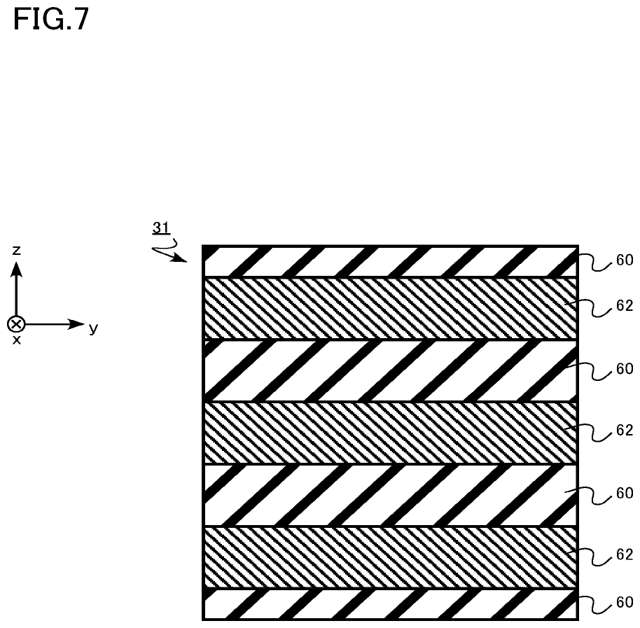

FIGS. 7, 8, 9, 10, 11, 12, 13, 14, and 15 are schematic sectional views illustrating an example of the method for manufacturing the semiconductor memory device of the second embodiment. FIGS. 7 to 15 each illustrate a section corresponding to FIG. 6A. FIGS. 7 to 15 are views illustrating an example of a method for manufacturing the memory cell array 200 of the semiconductor memory device.

First, silicon oxide layers 60 and silicon nitride layers 62 are alternately stacked on a semiconductor substrate (not illustrated) (FIG. 7). A stacked structure 31 is formed in which the silicon oxide layers 60 and the silicon nitride layers 62 are alternately stacked in the z direction. A part of the stacked structure 31 finally serves as a part of the stacked body 30.

The silicon oxide layers 60 and the silicon nitride layers 62 are formed with, for example, a chemical vapor deposition method (CVD method). A part of each silicon oxide layer 60 finally serves as the interlayer insulating layer 13.

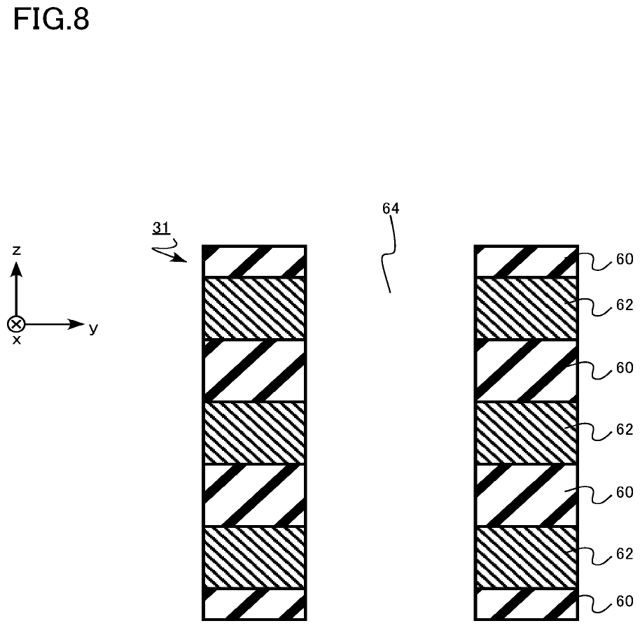

Next, a memory hole 64 is formed in the silicon oxide layers 60 and the silicon nitride layers 62 (FIG. 8). The memory hole 64 penetrates the stacked structure 31 and extends in the z direction. The memory hole 64 is formed with, for example, a lithography method and a reactive ion etching method (RIE method).

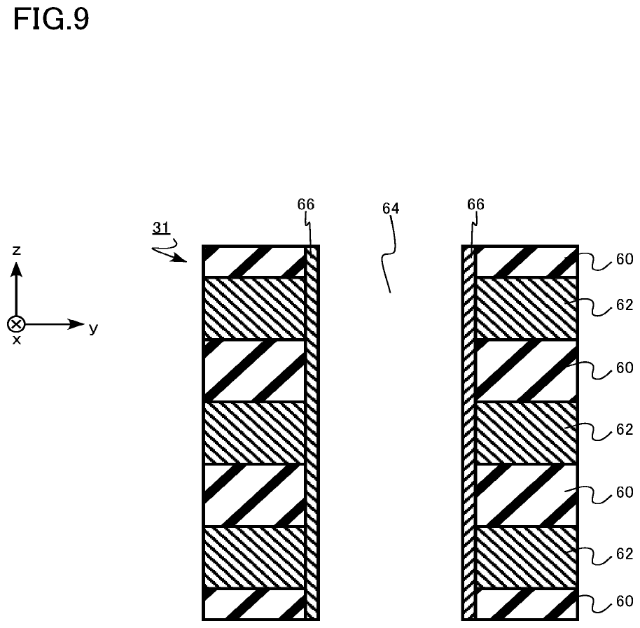

Next, a silicon oxide film 66 is formed on the inner wall of the memory hole 64 (FIG. 9). The silicon oxide film 66 is formed with, for example, a CVD method. The silicon oxide film 66 finally serves as the second block insulating layer 19.

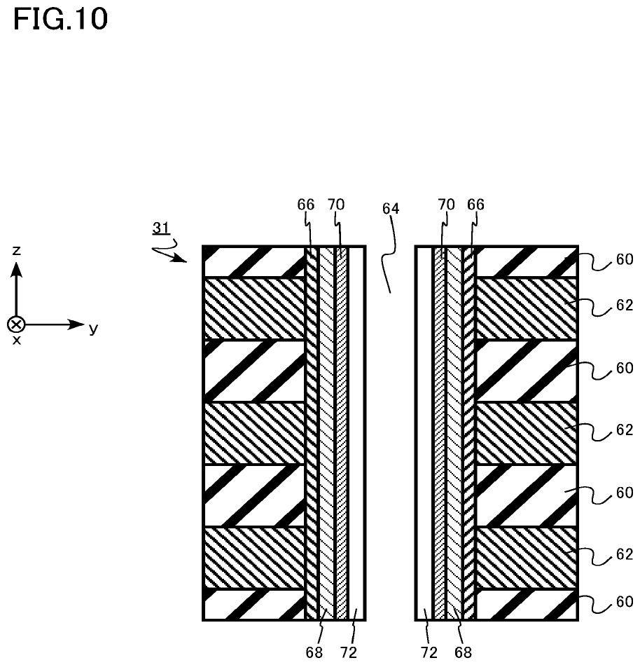

Next, a silicon nitride film 68 is formed on the silicon oxide film 66 (FIG. 10). The silicon nitride film 68 is formed with, for example, an ALD method. The silicon nitride film 68 finally serves as the charge storage layer 16.

Next, a stacked insulating film 70 is formed on the silicon nitride film 68 (FIG. 10). The stacked insulating film 70 is, for example, a stacked film of a silicon oxide film, a silicon nitride film, and a silicon oxide film.

The stacked insulating film 70 is formed with, for example, a CVD method. The stacked insulating film 70 finally serves as the tunnel insulating layer 14.

Next, a polycrystalline silicon film 72 is formed on the stacked insulating film 70 (FIG. 10). The polycrystalline silicon film 72 is formed with, for example, a CVD method. The polycrystalline silicon film 72 finally serves as the semiconductor layer 10.

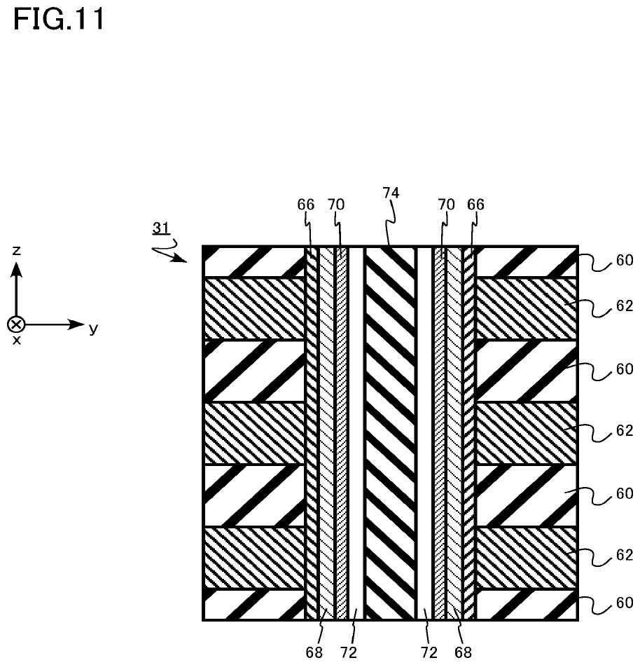

Next, the memory hole 64 is filled with a silicon oxide film 74 (FIG. 11). The silicon oxide film 74 is formed on the polycrystalline silicon film 72. The silicon oxide film 74 is formed with, for example, a CVD method. The silicon oxide film 74 finally serves as the core insulating region 20.

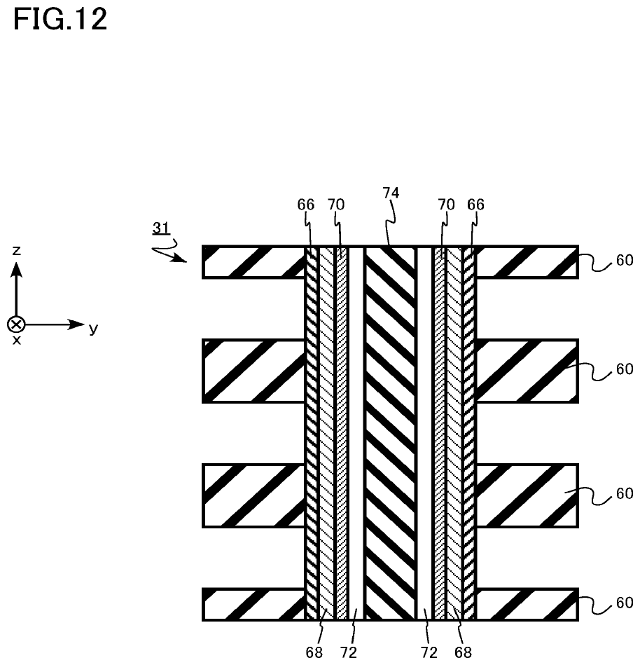

Next, the silicon nitride layers 62 are selectively removed with wet etching using an etching groove (not illustrated) (FIG. 12). For the wet etching, for example, a phosphoric acid solution is used. The silicon nitride layers 62 are selectively removed with etching in contrast to the silicon oxide layers 60 and the silicon oxide film 66.

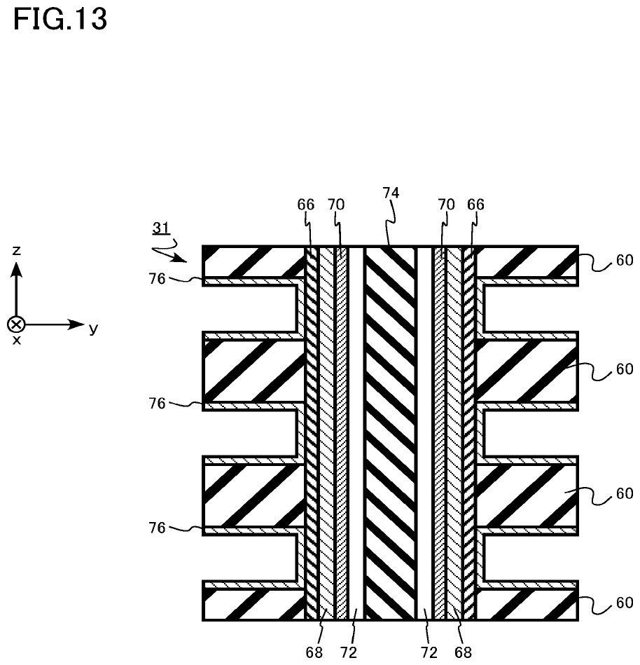

Next, aluminum nitride films 76 are formed in the regions where the silicon nitride layers 62 have been removed (FIG. 13). Each aluminum nitride film 76 has a thickness of, for example, equal to or more than 0.5 nm and less than 2.5 nm. The aluminum nitride film 76 is formed with, for example, an ALD method.

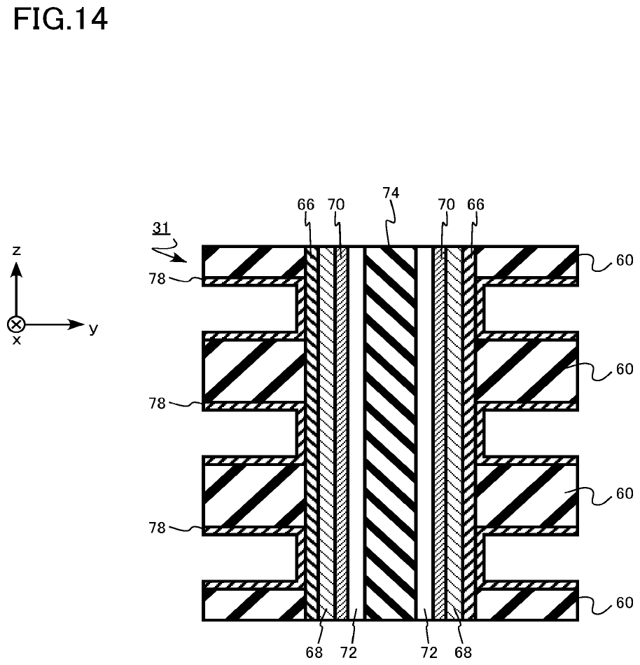

Next, the aluminum nitride film 76 is oxidized to form an aluminum oxide film 78 (FIG. 14). The aluminum nitride film 76 is oxidized, for example, at a temperature of equal to or more than 900° C. and equal to or less than 1,150° C.

The aluminum nitride film 76 is oxidized, for example, in an atmosphere containing hydrogen. The aluminum nitride film 76 is oxidized, for example, in an atmosphere containing an oxygen gas and a hydrogen gas. The aluminum nitride film 76 is oxidized, for example, by ISSG.

The aluminum oxide film 78 finally serves as the first block insulating layer 18.

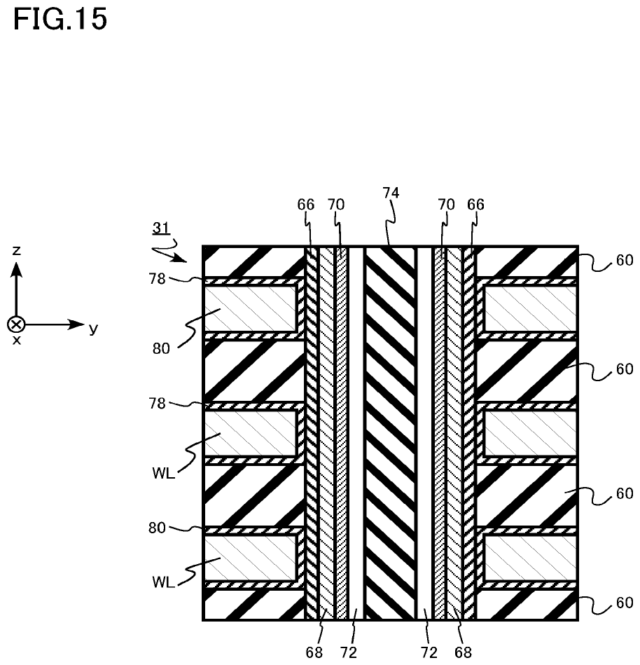

Next, a tungsten film 80 is formed on the aluminum oxide film 78 (FIG. 15). The tungsten film 80 is formed with, for example, a CVD method.

The tungsten film 80 finally serves as the word line WL. Before the tungsten film 80 is formed, for example, a barrier metal film such as a titanium nitride film can be also formed.

The memory cell array 200 of the semiconductor memory device of the second embodiment illustrated in FIG. 6 is manufactured with the above-described method.

Next, functions and effects of the semiconductor memory device of the second embodiment will be described.

A three-dimensional NAND flash memory in which memory cells are three-dimensionally disposed achieves a high degree of integration and a low cost. The three-dimensional NAND flash memory includes, for example, a stacked body in which a plurality of insulating layers and a plurality of gate electrode layers are alternately stacked, and a memory hole formed so as to penetrate the stacked body. In the memory hole, a charge storage layer and a semiconductor layer are formed to form a memory string in which a plurality of memory cells are connected in series. Each memory cell has a block insulating layer to inhibit the charges held in the charge storage layer from leaking into the gate electrode. For scaling-down, the memory cell is to have a block insulating layer achieving a small thickness and a small leakage current.

The memory cell array 200 of the three-dimensional NAND flash memory of the second embodiment includes the first block insulating layer 18. The first block insulating layer 18 has a thickness as small as equal to or less than 2.5 nm.

The fact that the first block insulating layer 18 has a small thickness promotes scaling-down of the memory cell. The fact that the first block insulating layer 18 has a small thickness allows, for example, reduction in size of the memory cell in the z direction, the x direction, and the y direction. Therefore, for example, the number of memory cells of the three-dimensional NAND flash memory is easily increased to increase the capacity of the three-dimensional NAND flash memory.

The aluminum oxide included in the first block insulating layer 18 includes at least one crystal phase selected from the group consisting of α-aluminum oxide and θ-aluminum oxide. The aluminum oxide included in the first block insulating layer 18 includes α-aluminum oxide or θ-aluminum oxide, or includes both α-aluminum oxide and θ-aluminum oxide, resulting in reduction in leakage current of the first block insulating layer 18. α-Aluminum oxide and θ-aluminum oxide are considered to achieve a smaller leakage current than other crystal phases such as γ-aluminum oxide.

From the viewpoint of reducing the leakage current of the first block insulating layer 18, at least one crystal phase selected from the group consisting of α-aluminum oxide and θ-aluminum oxide is preferably the main crystal phase among the crystal phases of the aluminum oxide included in the first block insulating layer 18. The term “main crystal phase” means a crystal phase having a higher existence ratio than other crystal phases.

The aluminum oxide in the first block insulating layer 18 has a crystal axis in a direction within a range of ±10 degrees with respect to the y direction. That is, the aluminum oxide in the first block insulating layer 18 is uniaxially oriented. The uniaxial orientation of the aluminum oxide in the first block insulating layer 18 leads to reduction in leakage current of the first block insulating layer 18. The reason for reduction in leakage current is considered to be increase in crystallinity of the aluminum oxide in the first block insulating layer 18.

From the viewpoint of reducing the leakage current of the first block insulating layer 18, the aluminum oxide in the first block insulating layer 18 preferably has a crystal axis in a direction within a range of ±5 degrees with respect to the y direction.

The reduction in leakage current of the first block insulating layer 18 leads to reduction in leakage current flowing between the charge storage layer 16 and the word line WL. Therefore, the charges stored in the charge storage layer 16 can be inhibited from leaking into the word line WL, and the charges in the word line WL can be inhibited from being injected into the charge storage layer 16. Therefore, for example, erroneous data writing can be inhibited at the time of erasing the charges stored in the charge storage layer 16.

The first block insulating layer 18 preferably has a thickness of equal to or less than 2.0 nm in the y direction from the viewpoint of reducing the leakage current of the first block insulating layer 18.

As described above, according to the second embodiment, a semiconductor memory device including an insulating layer achieving a small leakage current can be provided.

### Third Embodiment

A semiconductor memory device of a third embodiment is different from the semiconductor memory device of the second embodiment in that the semiconductor memory device of the third embodiment includes a semiconductor layer extending in the direction parallel to the surface of the semiconductor substrate. Hereinafter, the same description as the description of the second embodiment will be partially omitted.

The semiconductor memory device of the third embodiment is a three-dimensional NAND flash memory. The memory cell of the semiconductor memory device of the third embodiment is a so-called MONOS memory cell.

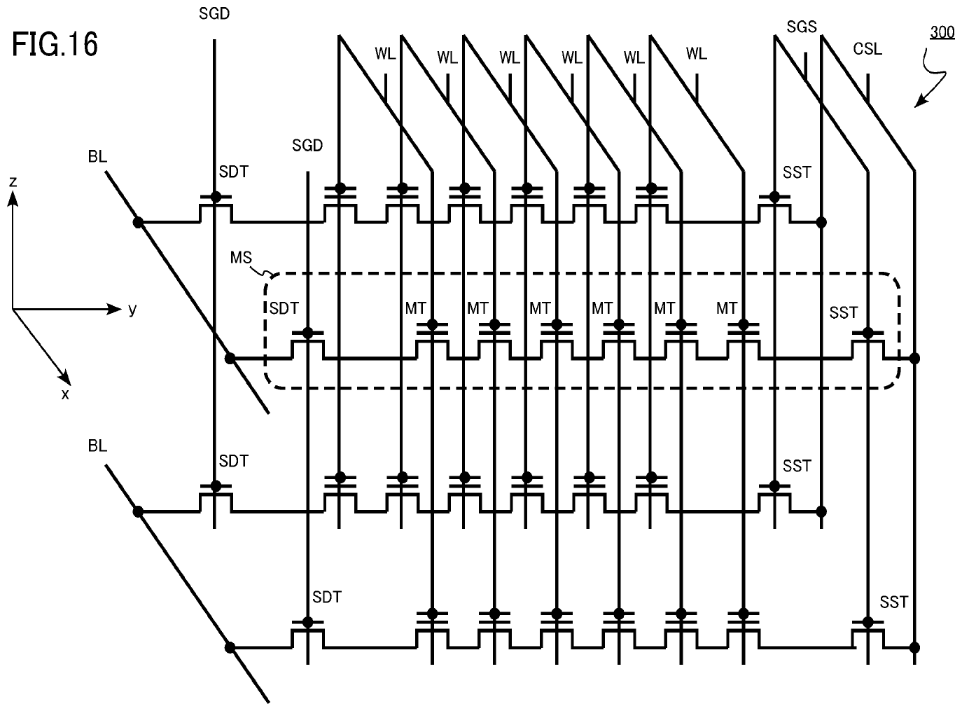

FIG. 16 is a circuit diagram of the memory cell array of the semiconductor memory device of the third embodiment.

As illustrated in FIG. 16, a memory cell array 300 of the three-dimensional NAND flash memory of the third embodiment includes a plurality of word lines WL, a common source line CSL, a source selection gate line SGS, a plurality of drain selection gate lines SGD, a plurality of bit lines BL, and a plurality of memory strings MS. Each word line WL is an example of the gate electrode layer.

The word lines WL are disposed apart from each other in the y direction. The memory strings MS extend in the y direction. The bit lines BL extend, for example, in the x direction.

Hereinafter, the x direction is defined as the second direction, the y direction is defined as the first direction, and the z direction is defined as the third direction. The x direction, the y direction, and the z direction cross each other, and are, for example, perpendicular to each other.

As illustrated in FIG. 16, each memory string MS includes a source selection transistor SST, a plurality of memory cells, and a drain selection transistor SDT connected in series between the common source line CSL and the bit line BL. One bit line BL and one drain selection gate line SGD are selected to select one memory string MS, and one word line WL can be selected to select one memory cell. The word line WL is a gate electrode of the memory cell transistor MT included in the memory cell.

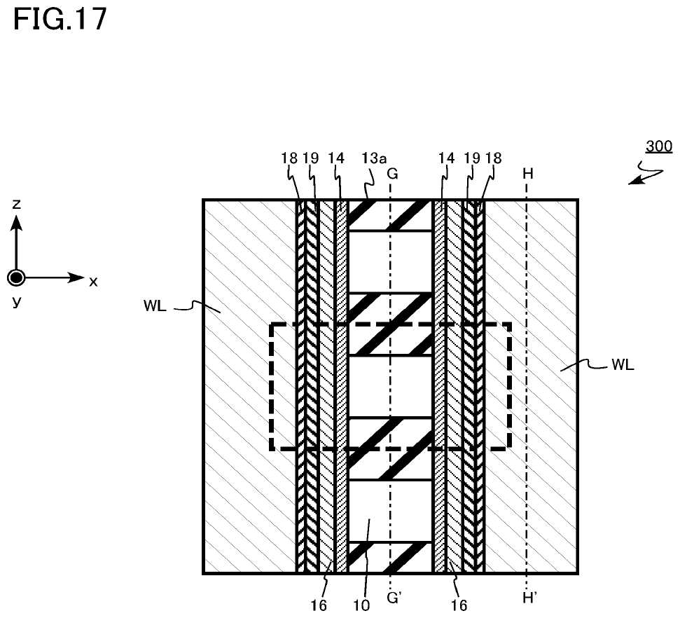

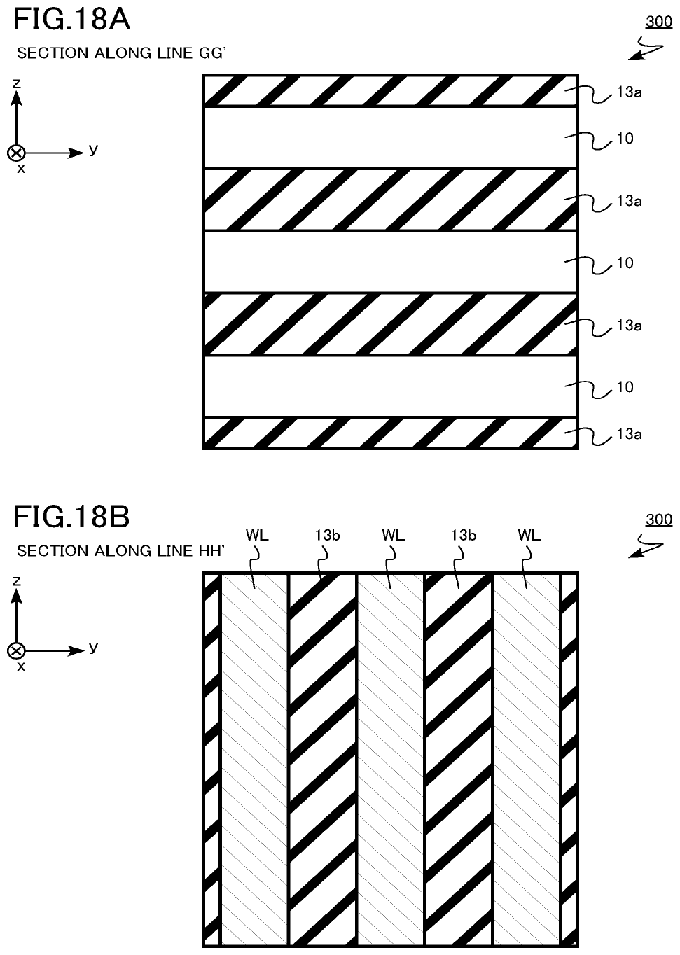

FIGS. 17, 18A, and 18B are schematic sectional views of the memory cell array of the semiconductor memory device of the third embodiment. FIGS. 17, 18A, and 18B illustrate a section of the memory cells in the memory strings MS in the memory cell array 300 of FIG. 16.

FIG. 17 is an xz sectional view of the memory cell array 300. In FIG. 17, the region surrounded by the broken line is one memory cell. FIG. 18A illustrates the section along the line GG′ in FIG. 17. FIG. 18A is a yz sectional view of the memory cell array 300. FIG. 18B illustrates the section along the line HH′ in FIG. 17. FIG. 18B is a yz sectional view of the memory cell array 300.

As illustrated in FIGS. 17, 18A, and 18B, the memory cell array 300 includes word lines WL, semiconductor layers 10, interlayer insulating layers 13a, interlayer insulating layers 13b, tunnel insulating layers 14, charge storage layers 16, first block insulating layers 18, and second block insulating layers 19.

Each word line WL is an example of the gate electrode layer. The tunnel insulating layer 14 is an example of the second insulating layer. Each first block insulating layer 18 is an example of the first insulating layer. Each second block insulating layer 19 is an example of the third insulating layer.

The memory cell array 300 is provided, for example, on a semiconductor substrate (not illustrated). The semiconductor substrate has a surface parallel to the x direction and the y direction.

The word lines WL and the interlayer insulating layers 13b are alternately disposed on the semiconductor substrate in the y direction. The word lines WL are disposed apart from each other in the y direction. The word lines WL are disposed apart from each other in the y direction repeatedly. Each word line WL functions as a control electrode of the memory cell transistor MT.

Each interlayer insulating layer 13b separates two word lines WL. The interlayer insulating layer 13b electrically separates two word lines WL. Each interlayer insulating layer 13a separates two semiconductor layers 10. The interlayer insulating layer 13a electrically separates two semiconductor layers 10.

The interlayer insulating layer 13a and the interlayer insulating layer 13b are, for example, an oxide, an oxynitride, or a nitride. The interlayer insulating layer 13a and the interlayer insulating layer 13b are, for example, silicon oxide. The interlayer insulating layer 13a has a thickness of, for example, equal to or more than 5 nm and equal to or less than 20 nm in the z direction.

The interlayer insulating layer 13b has a thickness of, for example, equal to or more than 5 nm and equal to or less than 20 nm in the y direction.

The semiconductor layer 10 extends in the y direction. The semiconductor layer 10 extends in the direction parallel to the surface of the semiconductor substrate. The semiconductor layer 10 is interposed between a plurality of word lines WL. The semiconductor layer 10 has, for example, a square column shape. The semiconductor layer 10 functions as a channel of the memory cell transistor MT.

The semiconductor layer 10 is, for example, a polycrystalline semiconductor. The semiconductor layer 10 is, for example, polycrystalline silicon.

The tunnel insulating layer 14 is provided between the semiconductor layer 10 and the word line WL. The tunnel insulating layer 14 is provided between the semiconductor layer 10 and at least one of the word lines WL. The tunnel insulating layer 14 is provided between the semiconductor layer 10 and the charge storage layer 16.

The tunnel insulating layer 14 includes, for example, silicon (Si), nitrogen (N), and oxygen (O). The tunnel insulating layer 14 includes, for example, silicon oxide, silicon nitride, or silicon oxynitride.

The charge storage layer 16 is provided between the tunnel insulating layer 14 and the first block insulating layer 18. The charge storage layer 16 is provided between the tunnel insulating layer 14 and the second block insulating layer 19.

The charge storage layer 16 is, for example, an insulating layer. The charge storage layer 16 includes, for example, silicon (Si) and nitrogen (N). The charge storage layer 16 includes, for example, silicon nitride.

The first block insulating layer 18 and the second block insulating layer 19 are provided between the tunnel insulating layer 14 and the word line WL. The first block insulating layer 18 and the second block insulating layer 19 are provided between the charge storage layer 16 and the word line WL. The first block insulating layer 18 and the second block insulating layer 19 have a function of blocking the current flow between the charge storage layer 16 and the word line WL.

The first block insulating layer 18 is provided between the charge storage layer 16 and the word line WL. The first block insulating layer 18 is provided between the second block insulating layer 19 and the word line WL.

The first block insulating layer 18 is an insulating layer. The first block insulating layer 18 includes aluminum oxide. The first block insulating layer 18 is, for example, an aluminum oxide layer.

The aluminum oxide included in the first block insulating layer 18 includes at least one crystal phase selected from the group consisting of alpha (α)-aluminum oxide and theta (θ)-aluminum oxide.

α-Aluminum oxide has a crystal structure of a hexagonal crystal. θ-Aluminum oxide has a crystal structure of a monoclinic crystal.

The aluminum oxide included in the first block insulating layer 18 may include gamma (γ)-aluminum oxide. γ-Aluminum oxide has a crystal structure of a cubic crystal.

The aluminum oxide in the first block insulating layer 18 has a crystal axis in a direction within a range of ±10 degrees with respect to the x direction from the semiconductor layer 10 toward the word line WL. The aluminum oxide in the first block insulating layer 18 is uniaxially oriented. The aluminum oxide in the first block insulating layer 18 has a c-axis in a direction, for example, within a range of ±10 degrees with respect to the x direction.

The angle between the direction of the crystal axis of the aluminum oxide in the first block insulating layer 18 and the x direction can be determined, for example, as follows. A TEM image of a section of the first block insulating layer 18 is subjected to fast Fourier transform analysis to determine the spot array direction, and the spot array direction is compared with the x direction to determine the angle.

The first block insulating layer 18 has a thickness of, for example, equal to or more than 0.5 nm and equal to or less than 2.5 nm in the x direction from the semiconductor layer 10 toward the word line WL.

The second block insulating layer 19 is provided between the charge storage layer 16 and the first block insulating layer 18.

The second block insulating layer 19 is an insulating layer. The second block insulating layer 19 includes, for example, silicon (Si) and oxygen (O). The second block insulating layer 19 includes, for example, silicon oxide. The second block insulating layer 19 is, for example, a silicon oxide layer.

The second block insulating layer 19 has a thickness of, for example, equal to or more than 3 nm and equal to or less than 8 nm in the x direction.

The memory cell array 300 of the three-dimensional NAND flash memory of the third embodiment includes the first block insulating layer 18. The first block insulating layer 18 has a thickness as small as equal to or less than 2.5 nm.

The fact that the first block insulating layer 18 has a small thickness promotes scaling-down of the memory cell. The fact that the first block insulating layer 18 has a small thickness allows, for example, reduction in size of the memory cell in the x direction. Therefore, for example, the number of memory cells of the three-dimensional NAND flash memory is easily increased to increase the capacity of the three-dimensional NAND flash memory.

Furthermore, the leakage current of the first block insulating layer 18 is reduced to reduce the leakage current flowing between the charge storage layer 16 and the word line WL. Therefore, the charges stored in the charge storage layer 16 can be inhibited from leaking into the word line WL, and the charges in the word line WL can be inhibited from being injected into the charge storage layer 16. Therefore, for example, erroneous data writing can be inhibited at the time of erasing the charges stored in the charge storage layer 16.

As described above, according to the third embodiment, a semiconductor memory device including an insulating layer achieving a small leakage current can be provided as in the second embodiment.

In the second and third embodiments, a case in which the interlayer insulating layer 13 is provided between the word lines WL is described as an example, but the space between the word lines WL may be, for example, empty.

In the second embodiment, a structure in which the semiconductor layer 10 is surrounded by the word lines WL is described as an example, but a structure in which the semiconductor layer 10 is interposed between two divided word lines WL can be also employed. In the latter structure, the stacked body 30 can include double number of memory cells.

In addition, in the second embodiment, a structure in which one semiconductor layer 10 is provided in one memory hole is described as an example, but a structure in which a plurality of semiconductor layers 10 obtained by division into equal to or more than two are provided in one memory hole can be also employed. In the latter structure, the stacked body 30 can include double or greater number of memory cells.

In the second and third embodiments, a case in which the charge storage layer is an insulating layer is described as an example, but the charge storage layer may be a conductive layer, for example, a plurality of floating conductive layers electrically separated from each other.

While certain embodiments have been described, these embodiments have been presented by way of example only, and are not intended to limit the scope of the inventions. Indeed, the semiconductor device, the semiconductor memory device, and the method for manufacturing a semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer;
a gate electrode layer; and
a first insulating layer provided between the semiconductor layer and the gate electrode layer, the first insulating layer including aluminum oxide, the aluminum oxide including at least one crystal phase selected from the group consisting of alpha (α)-aluminum oxide and theta (θ)-aluminum oxide, the first insulating layer having a thickness of equal to or less than 2.5 nm in a first direction from the semiconductor layer toward the gate electrode layer.

2. The semiconductor device according to claim 1, wherein the aluminum oxide in the first insulating layer has a crystal axis in a direction within a range of ±10 degrees with respect to the first direction.

3. The semiconductor device according to claim 2, wherein the crystal axis is a c-axis.

4. The semiconductor device according to claim 1, further comprising a second insulating layer provided between the semiconductor layer and the first insulating layer, the second insulating layer including silicon (Si) and oxygen (O).

5. A semiconductor device comprising:
a semiconductor layer;
a gate electrode layer; and
a first insulating layer provided between the semiconductor layer and the gate electrode layer, the first insulating layer including aluminum oxide, the aluminum oxide including at least one crystal phase selected from the group consisting of alpha (α)-aluminum oxide and theta (θ)-aluminum oxide, the aluminum oxide having a crystal axis in a direction within a range of ±10 degrees with respect to a first direction from the semiconductor layer toward the gate electrode layer.

6. The semiconductor device according to claim 5, wherein the crystal axis is a c-axis.

7. The semiconductor device according to claim 5, further comprising a second insulating layer provided between the semiconductor layer and the first insulating layer, the second insulating layer including silicon (Si) and oxygen (O).

8. A semiconductor memory device comprising:
a semiconductor layer extending in a first direction;
a gate electrode layer;
a charge storage layer provided between the semiconductor layer and the gate electrode layer;
a first insulating layer provided between the charge storage layer and the gate electrode layer, the first insulating layer including aluminum oxide, the aluminum oxide including at least one crystal phase selected from the group consisting of alpha (α)-aluminum oxide and theta (θ)-aluminum oxide, the first insulating layer having a thickness of equal to or less than 2.5 nm in a second direction from the semiconductor layer toward the gate electrode layer; and
a second insulating layer provided between the charge storage layer and the semiconductor layer.

9. The semiconductor memory device according to claim 8, wherein the aluminum oxide in the first insulating layer has a crystal axis in a direction within a range of ±10 degrees with respect to the second direction.

10. The semiconductor memory device according to claim 9, wherein the crystal axis is a c-axis.

11. The semiconductor memory device according to claim 8, further comprising a third insulating layer provided between the charge storage layer and the first insulating layer, the third insulating layer including silicon (Si) and oxygen (O).

12. The semiconductor memory device according to claim 8, further comprising a fourth insulating layer, wherein the gate electrode layer and the fourth insulating layer are arranged in the first direction, and the first insulating layer is provided between the gate electrode layer and the fourth insulating layer.

13. A semiconductor memory device comprising:
a semiconductor layer extending in a first direction;
a gate electrode layer;
a charge storage layer provided between the semiconductor layer and the gate electrode layer;
a first insulating layer provided between the charge storage layer and the gate electrode layer, the first insulating layer including aluminum oxide, the aluminum oxide including at least one crystal phase selected from the group consisting of alpha (α)-aluminum oxide and theta (θ)-aluminum oxide, the aluminum oxide having a crystal axis in a direction within a range of ±10 degrees with respect to a second direction from the semiconductor layer toward the gate electrode layer; and
a second insulating layer provided between the charge storage layer and the semiconductor layer.

14. The semiconductor memory device according to claim 13, wherein the crystal axis is a c-axis.

15. The semiconductor memory device according to claim 13, further comprising a third insulating layer provided between the charge storage layer and the first insulating layer, the third insulating layer including silicon (Si) and oxygen (O).

16. The semiconductor memory device according to claim 13, further comprising a fourth insulating layer, wherein the gate electrode layer and the fourth insulating layer are arranged in the first direction, and the first insulating layer is provided between the gate electrode layer and the fourth insulating layer.

17. A method for manufacturing a semiconductor device, the method comprising:
forming a first aluminum nitride film having a thickness of less than 2.5 nm; and
forming a first aluminum oxide film by oxidizing the first aluminum nitride film at a temperature of equal to or more than 900° C.

18. The method for manufacturing the semiconductor device according to claim 17, wherein, in the forming the first aluminum oxide film, the first aluminum nitride film is oxidized in an atmosphere containing an oxygen gas and a hydrogen gas.

19. The method for manufacturing the semiconductor device according to claim 17, wherein the first aluminum oxide film is formed on a silicon oxide film.

20. The method for manufacturing the semiconductor device according to claim 17, further comprising:
forming a second aluminum nitride film having a thickness of less than 2.5 nm on the first aluminum oxide film; and
forming a second aluminum oxide film by oxidizing the second aluminum nitride film at a temperature of equal to or more than 900° C.

21. The method for manufacturing the semiconductor device according to claim 17, further comprising:
forming a gate electrode layer after the forming the first aluminum oxide film,
wherein the first aluminum nitride film is formed on a semiconductor layer.
